(19) United States
(12) Patent Application Publication
(10) Pub. No.: US 2026/0113974 A1
(43) Pub. Date: Apr. 23, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroki NEMOTO, Meguro Tokyo (JP); Tomoaki INOKUCHI, Yokohama Kanagawa (JP); Tatsuya NISHIWAKI, Yokohama Kanagawa (JP); Shotaro BABA, Kawasaki Kanagawa (JP); Taichi FUKUDA, Yokohama Kanagawa (JP); Yusuke KOBAYASHI, Yokohama Kanagawa (JP); Hiro GANGI, Marugame Kagawa (JP); Kairu YOSHIDA, Kawasaki Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/241,540

(22) Filed: Jun. 18, 2025

(30) Foreign Application Priority Data
Oct. 17, 2024 (JP) 2024-182107

(51) Int. Cl. H10D 30/63; H10D 62/10; H10D 62/60; H10D 62/80; H10D 62/832; H10D 62/85; H10D 64/00; H10D 64/23; H10D 64/27; H10D 64/62; H10D 64/64

(52) U.S. Cl. CPC H10D 30/63; H10D 62/102; H10D 62/126; H10D 62/60; H10D 62/8325; H10D 62/8503; H10D 62/875; H10D 64/112; H10D 64/117; H10D 64/2527; H10D 64/513; H10D 64/62; H10D 64/647

(57) ABSTRACT

According to one embodiment, a semiconductor device include first to third electrodes, a first conductive member, a semiconductor member, and a first insulating member. The first conductive member is electrically connected to the second electrode. The first conductive member includes a first conductive portion and a second conductive portion. A first distance between the first electrode and the first conductive portion is shorter than a second distance between the first electrode and the first portion. The semiconductor member is provided between the first electrode and the second electrode.

### CROSS-REFERENCE TO RELATED APPLICATIONS

This application is based upon and claims the benefit of priority from Japanese Patent Application No. 2024-182107, filed on Oct. 17, 2024; the entire contents of which are incorporated herein by reference.

### FIELD

Embodiments described herein relate generally to a semiconductor device.

### BACKGROUND

For example, it is desired to improve the characteristics of semiconductor devices.

### BRIEF DESCRIPTION OF THE DRAWINGS

FIGS. 1A and 1B are schematic cross-sectional views illustrating a semiconductor device according to a first embodiment;

FIG. 2 is a schematic cross-sectional view illustrating the semiconductor device according to the first embodiment;

FIG. 3 is a schematic plan view illustrating the semiconductor device according to the first embodiment;

FIGS. 4A and 4B are schematic cross-sectional views illustrating a semiconductor device according to the first embodiment;

FIG. 5 is a schematic cross-sectional view illustrating the semiconductor device according to the first embodiment;

FIGS. 6A and 6B are schematic cross-sectional views illustrating a semiconductor device according to the first embodiment;

FIG. 7 is a schematic cross-sectional view illustrating a semiconductor device according to the first embodiment;

FIGS. 8A and 8B are schematic cross-sectional views illustrating a semiconductor device according to the first embodiment; and

FIG. 9 is a graph illustrating the characteristics of a semiconductor device.

### DETAILED DESCRIPTION

According to one embodiment, a semiconductor device include a first electrode, a second electrode, a third electrode, a first conductive member, a semiconductor member, and a first insulating member. A direction from the first electrode to the second electrode is along a first direction. The first conductive member is electrically connected to the second electrode. A second direction from the third electrode to at least a part of the first conductive member crosses the first direction. The first conductive member extends along a third direction crossing a plane including the first direction and the second direction. The first conductive member includes a first conductive portion and a second conductive portion. A direction from the first conductive portion to the second conductive portion is along the third direction. The second conductive portion includes a first portion. A first distance along the first direction between the first electrode and the first conductive portion is shorter than a second distance along the first direction between the first electrode and the first portion. The semiconductor member is provided between the first electrode and the second electrode. The semiconductor member includes a first semiconductor layer of a first conductivity type and a second semiconductor layer of the first conductivity type. The first semiconductor layer includes a first partial region and a second partial region. The first partial region is between the first electrode and the third electrode in the first direction. The second partial region is between the first electrode and the first conductive member in the first direction. The second partial region is in contact with the first conductive portion. At least a part of the second semiconductor layer is between the third electrode and the first conductive portion in the second direction. The second semiconductor layer is not provided between the third electrode and the second conductive portion in the second direction. A second impurity concentration of the first conductivity type in the second semiconductor layer is higher than a first impurity concentration of the first conductivity type in the first semiconductor layer. The first insulating member is provided between the third electrode and the semiconductor member.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

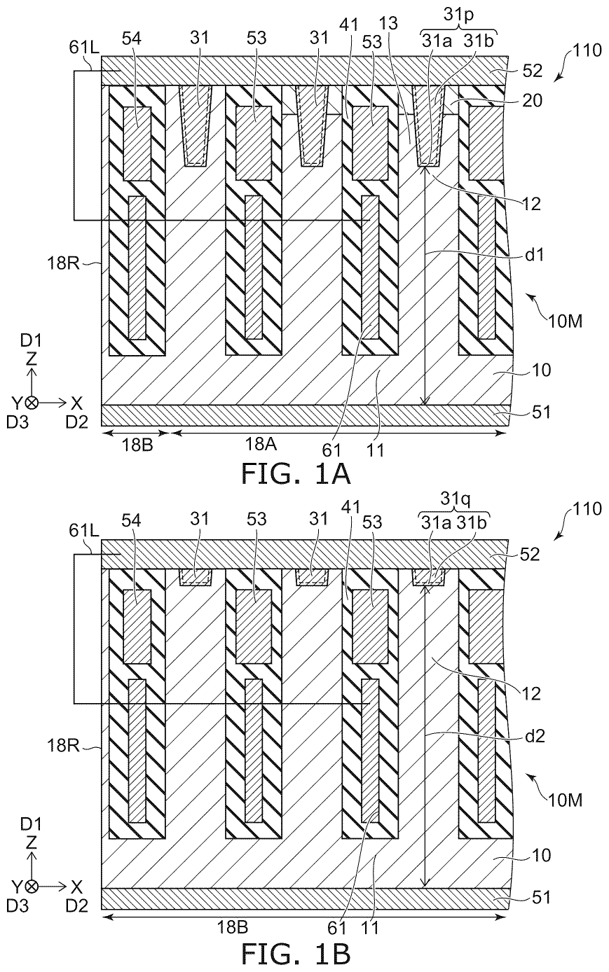

FIGS. 1A and 1B are schematic cross-sectional views illustrating a semiconductor device according to a first embodiment.

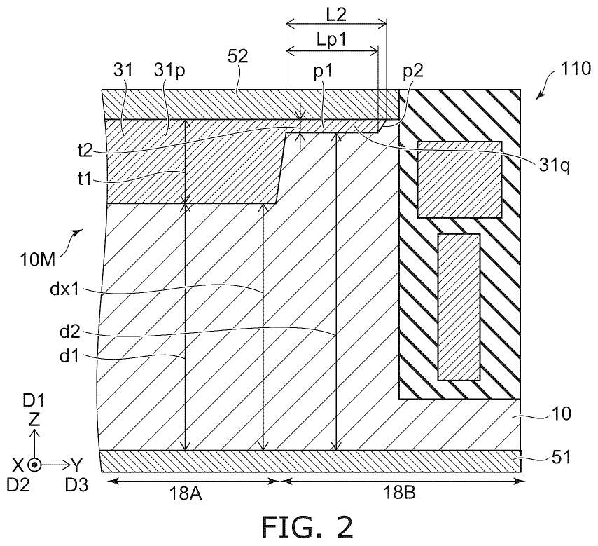

FIG. 2 is a schematic cross-sectional view illustrating the semiconductor device according to the first embodiment.

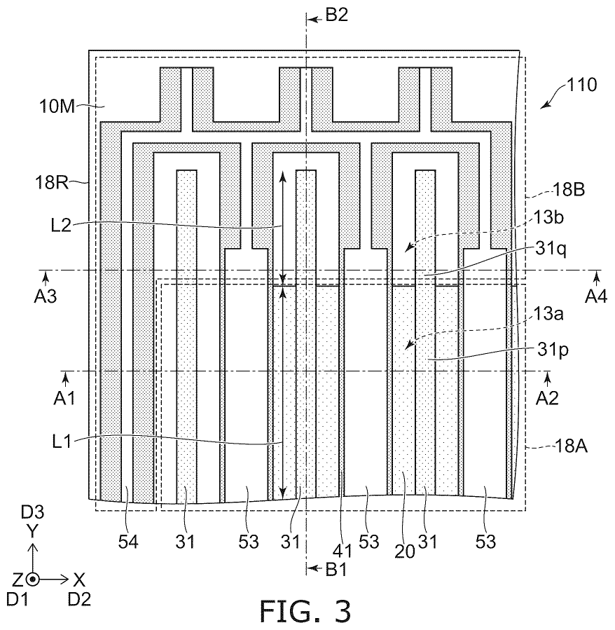

FIG. 3 is a schematic plan view illustrating the semiconductor device according to the first embodiment.

FIG. 1A is a cross-sectional view taken along the line A1-A2 in FIG. 3. FIG. 1B is a cross-sectional view taken along the line A3-A4 in FIG. 3. FIG. 2 is a cross-sectional view taken along line B1-B2 in FIG. 3.

As shown in FIGS. 1A, 1B, 2 and 3, a semiconductor device 110 according to the embodiment includes a first electrode 51, a second electrode 52, a third electrode 53, a first conductive member 31, a semiconductor member 10M, and a first insulating member 41. A direction from the first electrode 51 to the second electrode 52 is along a first direction D1.

The first direction D1 is defined as a Z-axis direction. One direction perpendicular to the Z-axis direction is defined as an X-axis direction. A direction perpendicular to the Z-axis direction and the X-axis direction is defined as a Y-axis direction.

The first conductive member 31 is electrically connected to the second electrode 52. A second direction D2 from the third electrode 53 to at least a part of the first conductive member 31 crosses the first direction D1. The second direction D2 may be, for example, the X-axis direction.

As shown in FIG. 2, the first conductive member 31 extends along a third direction D3. The third direction D3 crosses a plane including the first direction D1 and the second direction D2. The third direction D3 may be, for example, the Y-axis direction.

The first conductive member 31 includes a first conductive portion 31p and a second conductive portion 31q. A direction from the first conductive portion 31p to the second conductive portion 31q is along the third direction D3.

As shown in FIG. 2, the second conductive portion 31q includes a first portion p1. A distance between the first electrode 51 and the first conductive portion 31p in the first direction D1 is defined as a first distance d1. A distance between the first electrode 51 and the first portion p1 in the first direction D1 is defined as a second distance d2. The first distance d1 is shorter than the second distance d2.

As shown in FIG. 1A and FIG. 1B, the semiconductor member 10M is provided between the first electrode 51 and the second electrode 52. The semiconductor member 10M includes a first semiconductor layer 10 of a first conductivity type and a second semiconductor layer 20 of the first conductivity type. The first semiconductor layer 10 includes a first partial region 11 and a second partial region 12. The first partial region 11 is located between the first electrode 51 and the third electrode 53 in the first direction D1. The second partial region 12 is located between the first electrode 51 and the first conductive member 31 in the first direction D1. The second partial region 12 is in contact with the first conductive portion 31p.

At least a part of the second semiconductor layer 20 is located between the third electrode 53 and the first conductive portion 31p in the second direction D2. The second semiconductor layer 20 is not provided between the third electrode 53 and the second conductive portion 31q in the second direction D2. A second impurity concentration of the first conductivity type in the second semiconductor layer 20 is higher than a first impurity concentration of the first conductivity type in the first semiconductor layer 10.

The first insulating member 41 is provided between the third electrode 53 and the semiconductor member 10M. The first insulating member 41 electrically insulates between the third electrode 53 and the semiconductor member 10M. A part of the first insulating member 41 may be provided between the third electrode 53 and the second electrode 52. The first insulating member 41 electrically insulates the third electrode 53 from the second electrode 52.

Current flowing between the first electrode 51 and the second electrode 52 can be controlled by a potential of the third electrode 53. The potential of the third electrode 53 may be a potential based on a potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a transistor.

The current flowing between the first electrode 51 and the second electrode 52 may flow through the first conductive member 31. For example, a thickness of the barrier between the semiconductor member 10M and the first conductive member 31 can be controlled by the potential of the third electrode 53. The control of the current by the potential of the third electrode 53 may be based on control of the barrier thickness.

As described above, there are provided a region where the second semiconductor layer 20 is provided and a region where the second semiconductor layer 20 is not provided. The above-mentioned current control is performed in the region where the second semiconductor layer 20 is provided. The region where the second semiconductor layer 20 is provided corresponds to, for example, a switching region. The region where the second semiconductor layer 20 is not provided corresponds to, for example, a non-switching region.

In the embodiment, the second distance d2 between the second conductive portion 31q corresponding to the non-switching region and the first electrode 51 is longer than the first distance d1 between the first conductive portion 31p corresponding to the switching region and the first electrode 51. Thereby, for example, leakage current in the non-switching region is suppressed. This makes it possible to reduce power consumption. According to the embodiment, it is possible to provide a semiconductor device with improved characteristics.

In one example of the embodiment, the first distance d1 in the switching region can be set appropriately to obtain good on-characteristics. Meanwhile, the second distance d2 in the non-switching region is set appropriately to obtain good off-characteristics (e.g., small leakage current). In the embodiment, good off-characteristics are obtained while maintaining good on-characteristics.

For example, in a reference example in which the first distance d1 is the same as the second distance d2, it is difficult to obtain good off characteristics while maintaining good on characteristics. In the embodiment, by the second distance d2 corresponding to the non-switching region being long, for example, the leakage current pass is less likely to be formed.

As shown in FIG. 3, the semiconductor member 10M includes a cell region 18A, a terminal region 18B, and an outer edge 18R. The terminal region 18B is located between the cell region 18A and the outer edge 18R in a direction crossing the first direction D1. The first conductive portion 31p is provided in the cell region 18A. The second conductive portion 31q is provided in the terminal region 18B. According to the embodiment, for example, the leakage current in the terminal region 18B can be reduced.

As shown in FIG. 2, in this example, a second thickness t2 of the first portion p1 in the first direction D1 is thinner than a first thickness t1 of the first conductive portion 31p in the first direction D1.

As shown in FIG. 2, the second thickness t2 may be substantially constant. For example, the second conductive portion 31q may further include a second portion p2. The first portion p1 is between the first conductive portion 31p and the second portion p2 in the third direction D3. In the second portion p2, the thickness of the second portion p2 may vary. A first rate of change of the second thickness t2 with respect to a change in position along the third direction D3 may be lower than a second rate of change of the second portion thickness of the second portion p2 along the first direction D1 with respect to a change in position along the third direction D3. By the second thickness t2 of the first portion p1 being thin, the first distance d1 can be made shorter than the second distance d2.

For example, a ratio of an absolute value of a difference between the first thickness t1 and the second thickness t2 to the first thickness t1 may be not less than 0.05 and not more than 0.8. The leakage current can be effectively reduced. The ratio may be not less than 0.05 and not more than 0.5.

In the embodiment, the first thickness t1 may be, for example, not less than 500 nm and not more than 1000 nm. The second thickness t2 may be, for example, not less than 25 nm and not more than 800 nm. The first distance d1 may be, for example, not less than 50 μm and not more than 500 μm. The second distance d2 may be, for example, not less than 49 μm and not more than 499 μm.

As shown in FIG. 2, the first portion p1 has a first portion length Lp1 along the third direction D3. The second conductive portion 31q has a second conductive portion length L2 along the third direction D3. The first portion length Lp1 may be 0.5 times or more the second conductive portion length L2. This effectively reduces leakage current. The first portion length Lp1 may be 0.8 times or more the second conductive portion length L2.

As shown in FIG. 3, a first conductive portion length L1 of the first conductive portion 31p in the third direction D3 is longer than the second conductive portion length L2.

As shown in FIG. 2, in this example, the first portion p1 is continuous with the first conductive portion 31p. A first conductive member distance Dx1 along the first direction D1 between the first electrode 51 and the first conductive member 31 may change in a step shape between the first conductive portion 31p and the first portion p1.

The first distance d1 and second distance d2 described above can be obtained, for example, by processing (e.g., etching) using an appropriate mask.

As shown in FIG. 1A, a part of the first conductive portion 31p overlaps the third electrode 53 in the second direction D2. As shown in FIG. 1B, the second conductive portion 31q does not may not overlap the third electrode 53 in the second direction D2.

The second conductive portion 31q is located between a part of the first semiconductor layer 10 and another part of the first semiconductor layer 10 in the second direction D2. The second conductive portion 31q may be part of a trench-type contact region.

As shown in FIG. 1A, the first semiconductor layer 10 may further include a third partial region 13. The third partial region 13 is located between the third electrode 53 and the first conductive member 31 in the second direction D2.

The second partial region 12 forms a Schottky contact with the first conductive portion 31p. For example, the thickness of the Schottky barrier may be controlled by the potential of the third electrode 53. The third partial region 13 may form a Schottky contact with the first conductive portion 31p.

The semiconductor member 10M includes, for example, at least one selected from the group consisting of silicon, SiC, GaN, GaO, and GaAs.

As shown in FIGS. 1A and 1B, the first conductive member 31 includes a contact region 31a. The contact region 31a contacts the second partial region 12. The contact region 31a includes at least one selected from the group consisting of W, Ni, Co, Pt, Ir, and Au. A Schottky contact is effectively obtained. The contact region 31a may contact the third partial region 13. The first conductive member 31 may include a non-contact region 31b. The contact region 31a is located between the second partial region 12 and the non-contact region 31b. The contact region 31a is located between the third partial region 13 and the non-contact region 31b. The non-contact region 31b includes at least one selected from the group consisting of Al, Cu, W, Ti, Ni, and Au. The non-contact region 31b may include at least one selected from the group consisting of AlCu and TiN, for example. The non-contact region 31b provides, for example, a low electrical resistance.

As shown in FIGS. 1A and 1B, the semiconductor device 110 may further include a first conductive part 61. The first conductive part 61 is electrically connected to the second electrode 52. The first conductive part 61 may be electrically connected to the second electrode 52 by, for example, a wiring 61L.

A position (first conductive part position) of at least a part of the first conductive part 61 in the first direction D1 is between a position (first electrode position) of the first electrode 51 in the first direction D1 and a position (third electrode position) of the third electrode 53 in the first direction D1. A part of the first insulating member 41 is provided between the first conductive part 61 and the semiconductor member 10M, and between the first conductive part 61 and the third electrode 53. The first conductive part 61 suppresses the concentration of the electric field. The first conductive part 61 functions, for example, as a field plate.

For example, the first conductive part 61 is located between the first partial region 11 and the third electrode 53 in the first direction D1.

As shown in FIGS. 1A, 1B and 3, the semiconductor device 110 may further include a fourth electrode 54. The fourth electrode 54 is provided in the terminal region 18B. A direction from the fourth electrode 54 to the third electrode 53 crosses the first direction D1.

For example, a plurality of third electrodes 53 may be provided. The plurality of third electrodes 53 are arranged along the second direction D2. The plurality of third electrodes 53 extend along the third direction D3. A plurality of first conductive members 31 may be provided. The plurality of first conductive members 31 are arranged along the second direction D2. The plurality of first conductive members 31 extend along the third direction D3.

In the semiconductor device 110, one of the plurality of third electrodes 53 is provided between one of the plurality of first conductive members 31 and another one of the plurality of first conductive members 31. One of the plurality of first conductive members 31 is provided between one of the plurality of third electrodes 53 and another one of the plurality of third electrodes 53.

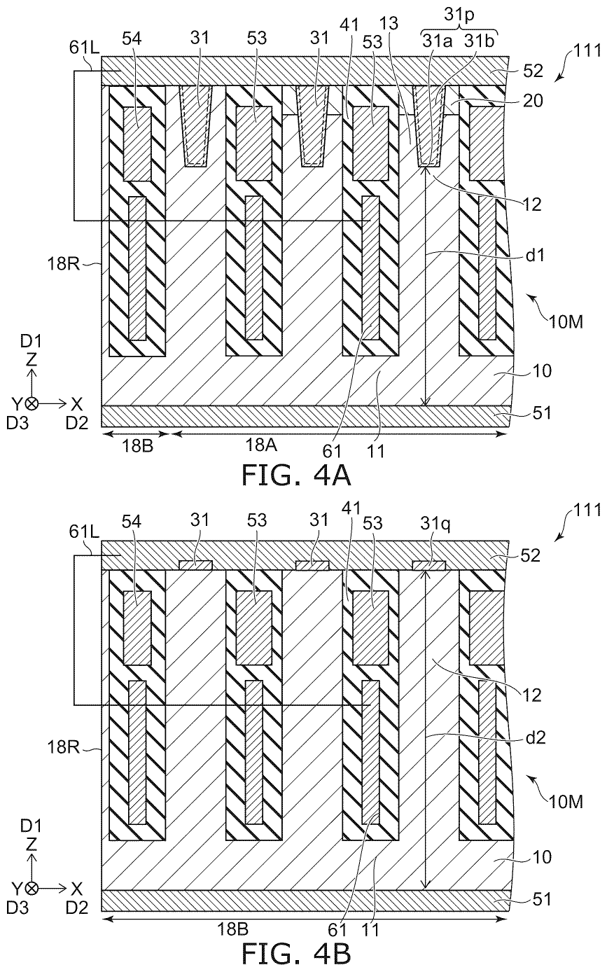

FIGS. 4A and 4B are schematic cross-sectional views illustrating a semiconductor device according to the first embodiment.

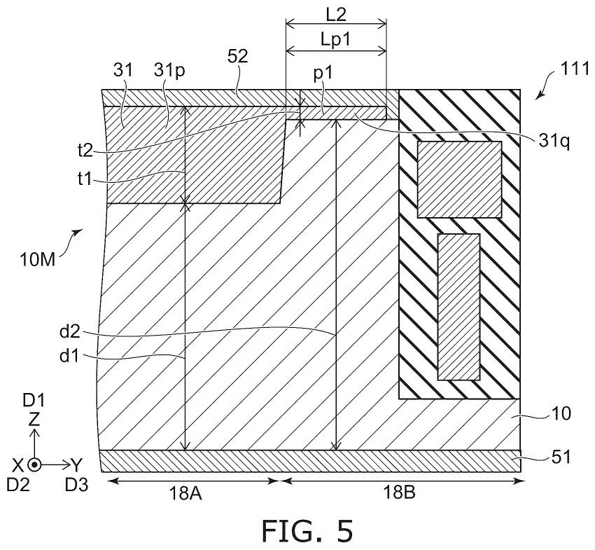

FIG. 5 is a schematic cross-sectional view illustrating the semiconductor device according to the first embodiment.

FIG. 4A is a cross-sectional view corresponding to the line A1-A2 in FIG. 3. FIG. 4B is a cross-sectional view corresponding to the line A3-A4 in FIG. 3. FIG. 5 is a cross-sectional view corresponding to the line B1-B2 in FIG. 3.

As shown in FIGS. 4A, 4B, and 5, in a semiconductor device 111 according to the embodiment, the second conductive portion 31q does not overlap the first semiconductor layer 10 in the second direction D2. Except for this, the configuration of the semiconductor device 111 may be the same as that of the semiconductor device 110. In the semiconductor device 111 as well, the first distance d1 is shorter than the second distance d2. For example, leakage current is suppressed. A semiconductor device capable of improving characteristics can be provided.

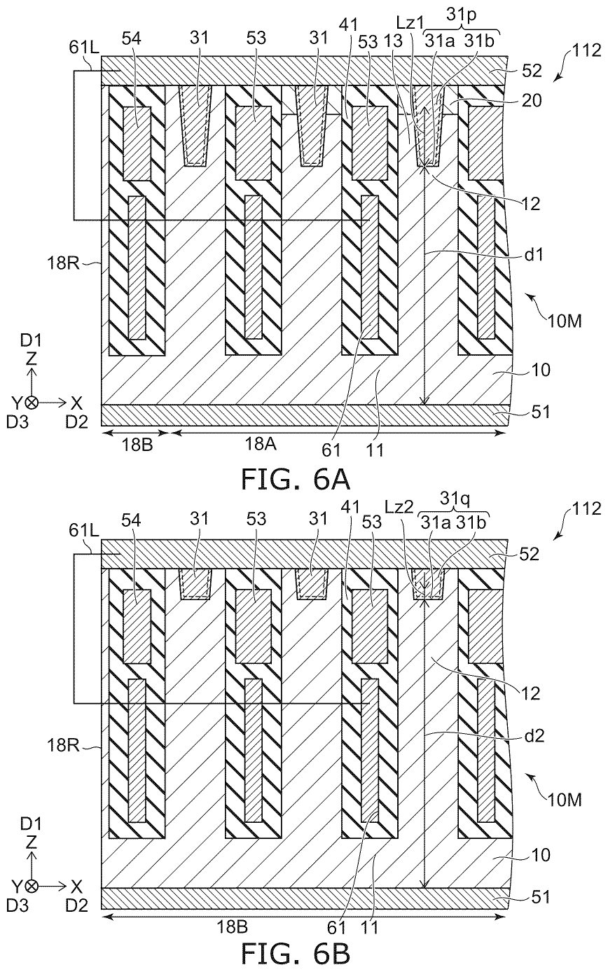

FIGS. 6A and 6B are schematic cross-sectional views illustrating a semiconductor device according to the first embodiment.

FIG. 6A is a cross-sectional view corresponding to the line A1-A2 in FIG. 3. FIG. 6B is a cross-sectional view corresponding to the line A3-A4 in FIG. 3. As shown in FIGS. 6A and 6B, in a semiconductor device 112 according to the embodiment, a part of the second conductive portion 31q overlaps the third electrode 53 in the second direction D2. Except for this, the configuration of the semiconductor device 112 may be the same as the configuration of the semiconductor device 110. In the semiconductor device 112 as well, the first distance d1 is shorter than the second distance d2. For example, leakage current is suppressed. A semiconductor device capable of improving characteristics can be provided.

As shown in FIG. 6A, a length along the first direction D1 of a part of the first conductive portion 31p that overlaps the third electrode 53 in the second direction D2 is defined as a first length Lz1. As shown in FIG. 6B, a length along the first direction D1 of a part of the second conductive portion 31q that overlaps the third electrode 53 in the second direction D2 is defined as a second length Lz2. The first length Lz1 is longer than the second length Lz2.

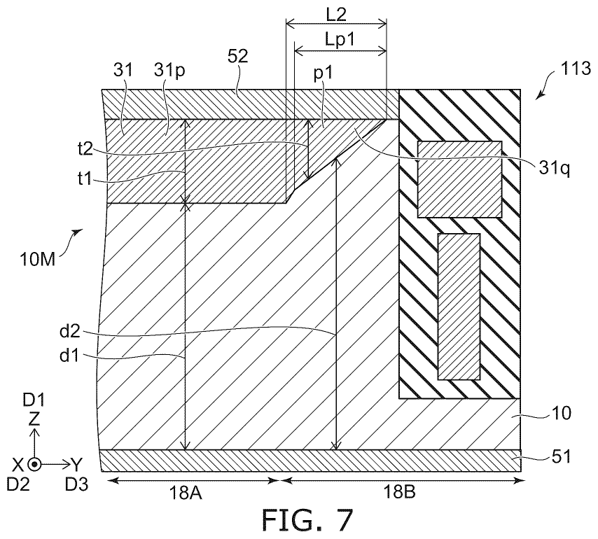

FIG. 7 is a schematic cross-sectional view illustrating a semiconductor device according to the first embodiment.

FIG. 7 is a cross-sectional view corresponding to the line B1-B2 in FIG. 3. As shown in FIG. 7, in a semiconductor device 113 according to the embodiment, the second thickness t2 in the first direction D1 of the first portion p1 decreases along the direction from the first conductive portion 31p to the second conductive portion 31q. Except for this, the configuration of the semiconductor device 113 may be the same as the configuration of the semiconductor device 110.

In at least a part of the first portion p1, a ratio of an absolute value of a difference between the first thickness t1 and the second thickness t2 to the first thickness t1 is 0.1 or more. The at least the part of the first portion p1 has a first portion length Lp1 along the third direction D3. The second conductive portion 31q has a second conductive portion length L2 along the third direction D3. The first portion length Lp1 is 0.5 times or more the second conductive portion length L2.

In the semiconductor device 113 having such a first thickness t1 and second thickness t2 as well, the first distance d1 is shorter than the second distance d2. For example, leakage current is suppressed. A semiconductor device with improved characteristics can be provided.

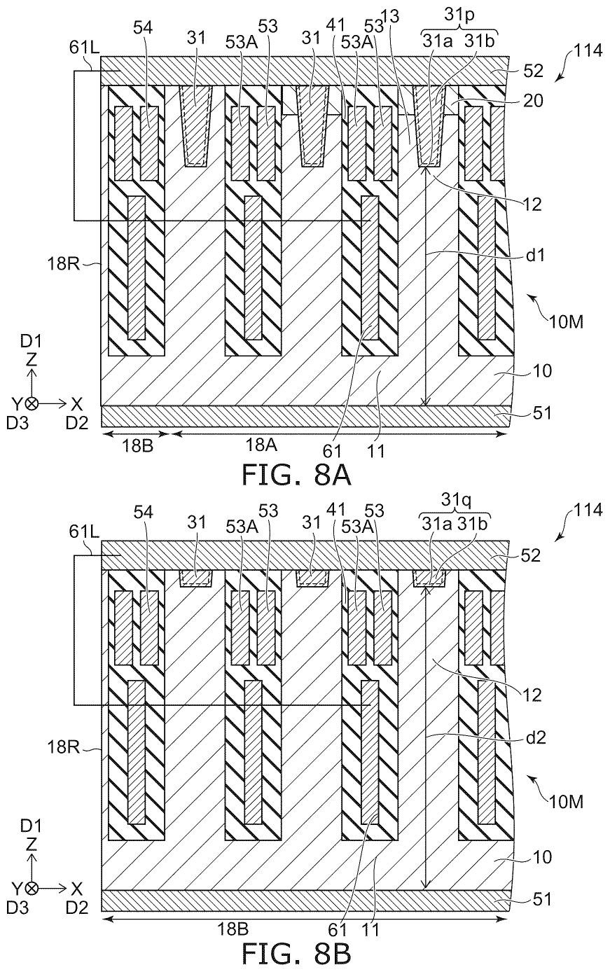

FIGS. 8A and 8B are schematic cross-sectional views illustrating a semiconductor device according to the first embodiment.

FIG. 8A is a cross-sectional view corresponding to the line A1-A2 in FIG. 3. FIG. 8B is a cross-sectional view corresponding to the line A3-A4 in FIG. 3.

As shown in FIGS. 8A and 8B, a semiconductor device 114 according to the embodiment further includes another third electrode 53A. Except for this, the configuration of the semiconductor device 114 may be the same as the configuration of the semiconductor device 110.

For example, the third electrode 53 is located between the other third electrode 53A and the first conductive member 31 in the second direction D2. In the semiconductor device 114 as well, the first distance d1 is shorter than the second distance d2. For example, leakage current is suppressed. A semiconductor device with improved characteristics can be provided.

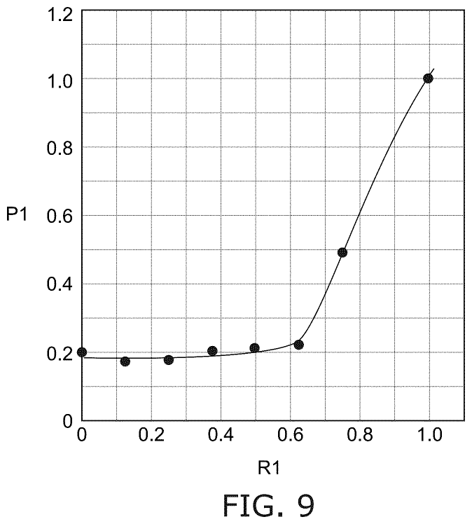

FIG. 9 is a graph illustrating the characteristics of a semiconductor device.

FIG. 9 illustrates a results of a simulation of the characteristics when the second length Lz2 in the semiconductor device 112 described above is changed. The horizontal axis of FIG. 9 is a length ratio R1. The length ratio R1 is a ratio of the second length Lz2 to the first length Lz1 (Lz2/Lz1) (see FIGS. 6A and 6B). When the length ratio R1 is 1, the depth of the second conductive portion 31q is the same as the depth of the first conductive portion 31p. The vertical axis is a leakage current parameter P1. The leakage current parameter P1 is normalized by a leakage current when the length ratio R1 is 1. It is preferable that the leakage current parameter P1 is small.

As shown in FIG. 9, a small leakage current parameter P1 is obtained when the length ratio R1 is 0.8 or less. This change is critical. In the embodiment, the length ratio R1 is preferably 0.625 or less. It is more preferable that the length ratio R1 is 0.6 or less. The length ratio R1 may be 0 or more.

In the embodiment, the first conductivity type is one of n-type and p-type. The first conductivity type may be, for example, n-type. The impurity concentration of the first conductivity type in the first semiconductor layer 10 may be, for example, not less than 1×10¹⁵ cm⁻³ and not more than 1×10¹⁷ cm⁻³. The impurity concentration of the first conductivity type in the second semiconductor layer 20 may be, for example, not less than 1×10¹⁸ cm⁻³ and not more than 1×10²¹ cm⁻³.

In the embodiment, at least one of the first electrode 51 or the second electrode 52 may include a metal. The metal may include, for example, at least one selected from the group consisting of Al, Ti, Ni, Au, Ag, and Cu. At least one of the third electrode 53 or the fourth electrode 54 may include polysilicon. In the embodiment, information regarding the shape of the semiconductor member is obtained, for example, from an electron microscope image. Information regarding the composition and element concentration is obtained, for example, from EDX (Energy Dispersive X-ray Spectroscopy) or SIMS (Secondary Ion Mass Spectrometry). Information regarding the composition may be obtained, for example, from reciprocal space mapping.

Embodiments may include the following Technical proposals:

### (Technical Proposal 1)

A semiconductor device, comprising:
a first electrode;
a second electrode, a direction from the first electrode to the second electrode being along a first direction;
a third electrode;
a first conductive member electrically connected to the second electrode, a second direction from the third electrode to at least a part of the first conductive member crossing the first direction, the first conductive member extending along a third direction crossing a plane including the first direction and the second direction, the first conductive member including a first conductive portion and a second conductive portion, a direction from the first conductive portion to the second conductive portion being along the third direction, the second conductive portion including a first portion, and a first distance along the first direction between the first electrode and the first conductive portion being shorter than a second distance along the first direction between the first electrode and the first portion;
a semiconductor member provided between the first electrode and the second electrode, the semiconductor member including a first semiconductor layer of a first conductivity type and a second semiconductor layer of the first conductivity type, the first semiconductor layer including a first partial region and a second partial region, the first partial region being between the first electrode and the third electrode in the first direction, the second partial region being between the first electrode and the first conductive member in the first direction, the second partial region being in contact with the first conductive portion, at least a part of the second semiconductor layer being between the third electrode and the first conductive portion in the second direction, the second semiconductor layer being not provided between the third electrode and the second conductive portion in the second direction, a second impurity concentration of the first conductivity type in the second semiconductor layer being higher than a first impurity concentration of the first conductivity type in the first semiconductor layer; and
a first insulating member provided between the third electrode and the semiconductor member.

### (Technical Proposal 2)

The semiconductor device according to Technical proposal 1, wherein
the semiconductor member includes a cell region, a terminal region, and an outer edge,
the terminal region is located between the cell region and the outer edge in a direction crossing the first direction,
the first conductive portion is provided in the cell region, and
the second conductive portion is provided in the terminal region.

### (Technical Proposal 3)

The semiconductor device according to Technical proposal 1 or 2, wherein
a second thickness of the first portion in the first direction is less than a first thickness of the first conductive portion in the first direction.

### (Technical Proposal 4)

The semiconductor device according to Technical proposal 3, wherein
the second conductive portion further includes a second portion,
the first portion is located between the first conductive portion and the second portion in the third direction,
a first rate of change of the second thickness with respect to a change in position along the third direction is lower than a second rate of change of a second portion thickness along the first direction with respect to the change in position along the third direction.
   (Technical proposal 5)

The semiconductor device according to Technical proposal 3, wherein
the second thickness is substantially constant.

### (Technical Proposal 6)

The semiconductor device according to any one of Technical proposals 3-5, wherein
a ratio of an absolute value of a difference between the first thickness and the second thickness to the first thickness is not less than 0.05 and not more than 0.8.

### (Technical Proposal 7)

The semiconductor device according to any one of Technical proposals 3-6, wherein
the first portion has a first portion length along the third direction,
the second conductive portion has a second conductive portion length along the third direction, and
the first portion length is 0.5 times or more the second conductive portion length.

### (Technical Proposal 8)

The semiconductor device according to Technical proposal 7, wherein
a first conductive portion length in the third direction of the first conductive portion is longer than the second conductive portion length.

### (Technical Proposal 9)

The semiconductor device according to Technical proposal 3, wherein
the second thickness decreases along a direction from the first conductive portion to the second conductive portion,
in at least a part of the first portion, a ratio of an absolute value of a difference between the first thickness and the second thickness to the first thickness is 0.1 or more,
the at least the part of the first portion has a first portion length along the third direction,
the second conductive portion has a second conductive portion length along the third direction, and
the first portion length is 0.5 times or more the second conductive portion length.

### (Technical Proposal 10)

The semiconductor device according to any one of Technical proposals 3-9, wherein
the first portion is continuous with the first conductive portion, and
a first conductive member distance along the first direction between the first electrode and the first conductive member changes stepwise between the first conductive portion and the first portion.

### (Technical Proposal 11)

The semiconductor device according to any one of Technical proposals 1-10, wherein
the second conductive portion does not overlap the third electrode in the second direction.

### (Technical Proposal 12)

The semiconductor device according to any one of Technical proposals 1-10, wherein
the second conductive portion is located between a part of the first semiconductor layer and another part of the first semiconductor layer in the second direction.

### (Technical Proposal 13)

The semiconductor device according to any one of Technical proposals 1-10, wherein
the second conductive portion does not overlap the first semiconductor layer in the second direction.

### (Technical Proposal 14)

The semiconductor device according to any one of Technical proposals 1-13, wherein
the second partial region forms a Schottky contact with the first conductive portion.

### (Technical Proposal 15)

The semiconductor device according to any one of Technical proposals 1-14, wherein
the semiconductor member includes at least one selected from the group consisting of silicon, SiC, GaN, GaO, and GaAs.

### (Technical Proposal 16)

The semiconductor device according to Technical proposal 15, wherein
the first conductive member includes a contact region, and
the contact region is in contact with the second partial region, and the contact region includes at least one selected from the group consisting of W, Ni, Co, Pt, Ir, and Au.

### (Technical Proposal 17)

The semiconductor device according to Technical proposal 16, wherein
the first conductive member includes a non-contact region,
the contact region is located between the second partial region and the non-contact region, and
the non-contact region includes at least one selected from the group consisting of Al, Cu, W, Ti, Ni, and Au.

### (Technical Proposal 18)

The semiconductor device according to any one of Technical proposals 1-17, wherein
the third electrode extends along the third direction.

### (Technical Proposal 19)

The semiconductor device according to any one of Technical proposals 1-18, further comprising:
a first conductive part electrically connected to the second electrode,
a first conductive part position of at least a part of the first conductive part in the first direction being between a first electrode position of the first electrode in the first direction and a third electrode position of the third electrode in the first direction, and
a part of the first insulating member is located between the first conductive part and the semiconductor member, and between the first conductive part and the third electrode.

### (Technical Proposal 20)

The semiconductor device according to any one of Technical proposals 1-19, further comprising:
a ratio of a second length to a first length is 0.625 or less,
the first length is a length along the first direction of a part of the first conductive portion overlapping the third electrode in the second direction,
the second length is a length along the first direction of a part of the second conductive portion overlapping the third electrode in the second direction.

According to the embodiment, a semiconductor device is provided that can improve characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, conductive members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction;
a third electrode;
a first conductive member electrically connected to the second electrode, a second direction from the third electrode to at least a part of the first conductive member crossing the first direction, the first conductive member extending along a third direction crossing a plane including the first direction and the second direction, the first conductive member including a first conductive portion and a second conductive portion, a direction from the first conductive portion to the second conductive portion being along the third direction, the second conductive portion including a first portion, and a first distance along the first direction between the first electrode and the first conductive portion being shorter than a second distance along the first direction between the first electrode and the first portion;
a semiconductor member provided between the first electrode and the second electrode, the semiconductor member including a first semiconductor layer of a first conductivity type and a second semiconductor layer of the first conductivity type, the first semiconductor layer including a first partial region and a second partial region, the first partial region being between the first electrode and the third electrode in the first direction, the second partial region being between the first electrode and the first conductive member in the first direction, the second partial region being in contact with the first conductive portion, at least a part of the second semiconductor layer being between the third electrode and the first conductive portion in the second direction, the second semiconductor layer being not provided between the third electrode and the second conductive portion in the second direction, a second impurity concentration of the first conductivity type in the second semiconductor layer being higher than a first impurity concentration of the first conductivity type in the first semiconductor layer; and
a first insulating member provided between the third electrode and the semiconductor member.

2. The semiconductor device according to claim 1, wherein
the semiconductor member includes a cell region, a terminal region, and an outer edge,
the terminal region is located between the cell region and the outer edge in a direction crossing the first direction,
the first conductive portion is provided in the cell region, and
the second conductive portion is provided in the terminal region.

3. The semiconductor device according to claim 1, wherein
a second thickness of the first portion in the first direction is less than a first thickness of the first conductive portion in the first direction.

4. The semiconductor device according to claim 3, wherein
the second conductive portion further includes a second portion,
the first portion is located between the first conductive portion and the second portion in the third direction,
a first rate of change of the second thickness with respect to a change in position along the third direction is lower than a second rate of change of a second portion thickness along the first direction with respect to the change in position along the third direction.

5. The semiconductor device according to claim 3, wherein
the second thickness is substantially constant.

6. The semiconductor device according to claim 3, wherein
a ratio of an absolute value of a difference between the first thickness and the second thickness to the first thickness is not less than 0.05 and not more than 0.8.

7. The semiconductor device according to claim 3, wherein
the first portion has a first portion length along the third direction,
the second conductive portion has a second conductive portion length along the third direction, and
the first portion length is 0.5 times or more the second conductive portion length.

8. The semiconductor device according to claim 7, wherein
a first conductive portion length in the third direction of the first conductive portion is longer than the second conductive portion length.

9. The semiconductor device according to claim 3, wherein
the second thickness decreases along a direction from the first conductive portion to the second conductive portion,
in at least a part of the first portion, a ratio of an absolute value of a difference between the first thickness and the second thickness to the first thickness is 0.1 or more,
the at least the part of the first portion has a first portion length along the third direction,
the second conductive portion has a second conductive portion length along the third direction, and
the first portion length is 0.5 times or more the second conductive portion length.

10. The semiconductor device according to claim 3, wherein
the first portion is continuous with the first conductive portion, and
a first conductive member distance along the first direction between the first electrode and the first conductive member changes stepwise between the first conductive portion and the first portion.

11. The semiconductor device according to claim 1, wherein
the second conductive portion does not overlap the third electrode in the second direction.

12. The semiconductor device according to claim 1, wherein
the second conductive portion is located between a part of the first semiconductor layer and another part of the first semiconductor layer in the second direction.

13. The semiconductor device according to claim 1, wherein
the second conductive portion does not overlap the first semiconductor layer in the second direction.

14. The semiconductor device according to claim 1, wherein
the second partial region forms a Schottky contact with the first conductive portion.

15. The semiconductor device according to claim 1, wherein
the semiconductor member includes at least one selected from the group consisting of silicon, SiC, GaN, GaO, and GaAs.

16. The semiconductor device according to claim 15, wherein
the first conductive member includes a contact region, and
the contact region is in contact with the second partial region, and the contact region includes at least one selected from the group consisting of W, Ni, Co, Pt, Ir, and Au.

17. The semiconductor device according to claim 16, wherein
the first conductive member includes a non-contact region,
the contact region is located between the second partial region and the non-contact region, and
the non-contact region includes at least one selected from the group consisting of Al, Cu, W, Ti, Ni, and Au.

18. The semiconductor device according to claim 1, wherein the third electrode extends along the third direction.

19. The semiconductor device according to claim 1, further comprising:
a first conductive part electrically connected to the second electrode,
a first conductive part position of at least a part of the first conductive part in the first direction being between a first electrode position of the first electrode in the first direction and a third electrode position of the third electrode in the first direction, and
a part of the first insulating member is located between the first conductive part and the semiconductor member, and between the first conductive part and the third electrode.

20. The semiconductor device according to claim 1, further comprising:
a ratio of a second length to a first length is 0.625 or less,
the first length is a length along the first direction of a part of the first conductive portion overlapping the third electrode in the second direction,
the second length is a length along the first direction of a part of the second conductive portion overlapping the third electrode in the second direction.
